(19) United States
(12) Patent Application Publication
(10) Pub. No.: US 2016/0083843 A1
(43) Pub. Date: Mar. 24, 2016

(54) SUBSTRATE PROCESSING APPARATUS

(71) Applicant: HITACHI KOKUSAI ELECTRIC INC., Tokyo (JP)

(72) Inventor: Tetsuo YAMAMOTO, Toyama-shi (JP)

(73) Assignee: HITACHI KOKUSAI ELECTRIC INC., Tokyo (JP)

(21) Appl. No.: 14/842,178

(22) Filed: Sep. 1, 2015

(30) Foreign Application Priority Data
Sep. 24, 2014 (JP) 2014-193742

(51) Int. Cl. C23C 16/455; C23C 16/44; C23C 16/52

(52) U.S. Cl. CPC C23C 16/45544; C23C 16/52; C23C 16/45565; C23C 16/4412; C23C 16/4557

(57) ABSTRACT

A substrate processing apparatus includes a process chamber configured to process a substrate; a shower head installed at an upstream side of the process chamber; a gas supply pipe connected to the shower head; a first exhaust pipe connected to a downstream side of the process chamber; a second exhaust pipe connected to a second wall surface, which is different from a first wall surface adjacent to the process chamber, in wall surfaces forming the shower head; a pressure detecting part installed in the second exhaust pipe; and a control part configured to control each of the process chamber, the shower head, the gas supply pipe, the first exhaust pipe, the second exhaust pipe, and the pressure detecting part.

### CROSS-REFERENCE TO RELATED APPLICATION

This application is based upon and claims the benefit of priority from Japanese Patent Application No. 2014-193742, filed on Sep. 24, 2014, the entire contents of which are incorporated herein by reference.

### TECHNICAL FIELD

The present disclosure relates to a substrate processing apparatus.

### BACKGROUND

Recently, semiconductor devices such as flash memories, etc. tend to be highly integrated. According to such a high integration, patterns have been remarkably reduced in size. In order to form the patterns, a certain process such as oxidization, nitridation, or the like may be performed on a substrate as one process of manufacturing processes.

As one method of forming such patterns, there is a process of forming grooves between circuits and forming a seed film, a liner film, a wiring, or the like therein. The grooves are configured to have a high aspect ratio according to the recent miniaturization trend.

When a liner film, etc. is formed, it is required to form a film with a good step coverage without a variation in a film thickness even in an upper side surface, a middle side surface, a lower side surface, and a bottom of a groove. Forming the film with the good step coverage may allow the characteristics of a semiconductor device to be uniform between the grooves, and thus, variations in the characteristics of the semiconductor device can be suppressed.

As an approach of hardware configuration that allows the characteristics of a semiconductor device to be uniform, for example, there is a shower head structure in a single-wafer-type apparatus. By forming gas dispersion holes over a substrate, a gas may be uniformly supplied.

Further, as a substrate processing method of allowing the characteristics of a semiconductor device to be uniform, for example, there is an alternate supply method that alternately supplies at least two types of process gases to react on a surface of a substrate. In the alternate supply method, in order to suppress each gas from reacting on portions other than the surface of the substrate, a residual gas is removed with a purge gas while each gas is supplied.

In order to further enhance film characteristics, the use of the alternate supply method in an apparatus that employs the shower head structure may be taken into consideration. In the case of such an apparatus, it may be considered that a path or a buffer space is provided for each gas in order to prevent the gases from being mixed. However, since the structure is complicated, it requires a great deal of care for maintenance and the cost increases as well. Thus, it is practical to use a shower head in which the supply systems of two types of gases and a purge gas are integrated into a single buffer space.

In the case of using a shower head having a buffer space that is common to two types of gases, a case in which residual gases react with each other within the shower head to deposit an extraneous matter on an inner wall of the shower head may be considered. In order to prevent this case, it is preferable that an exhaust hole is formed in a buffer chamber and atmosphere is evacuated from the exhaust hole such that a residual gas within the buffer chamber can be effectively removed.

However, when a predetermined film forming process continues, a byproduct or a gas may adhere to an inner wall of dispersed holes of a shower head to clog the dispersed holes. In this case, it is not possible to supply a desired amount of gas onto the substrate, and thus, a film with desired quality may not be formed.

### SUMMARY

The present disclosure provides some embodiments of a substrate processing apparatus, a method of manufacturing a semiconductor device, a program, and a recording medium, which are capable of restraining clogging of a gas dispersion plate in a shower head.

According to one embodiment of the present disclosure, there is provided a substrate processing apparatus, including: a process chamber configured to process a substrate; a shower head installed at an upstream side of the process chamber; a gas supply pipe connected to the shower head; a first exhaust pipe connected to a downstream side of the process chamber; a second exhaust pipe connected to a second wall surface, which is different from a first wall surface adjacent to the process chamber, in wall surfaces forming the shower head; a pressure detecting part installed in the second exhaust pipe; and a control part configured to control each of the process chamber, the shower head, the gas supply pipe, the first exhaust pipe, the second exhaust pipe, and the pressure detecting part.

### BRIEF DESCRIPTION OF THE DRAWINGS

FIG. 1 is a diagram of a substrate processing apparatus according to a first embodiment of the present disclosure.

FIG. 2 is an explanatory view of a first dispersion structure according to the first embodiment of the present disclosure.

FIG. 3 is an explanatory view of a pressure detector according to the first embodiment of the present disclosure.

FIG. 4 is a flowchart illustrating a substrate treatment process of the substrate processing apparatus shown in FIG. 1.

FIG. 5 is a flowchart illustrating the details of a film forming step shown in FIG. 4.

FIG. 6 is a flowchart illustrating an operation flow based on a detected pressure.

FIG. 7 is a table explaining a relationship between a detected pressure and a sensor condition.

### DETAILED DESCRIPTION

Hereinafter, a first embodiment of the present disclosure will be described.

### <Apparatus Configuration>

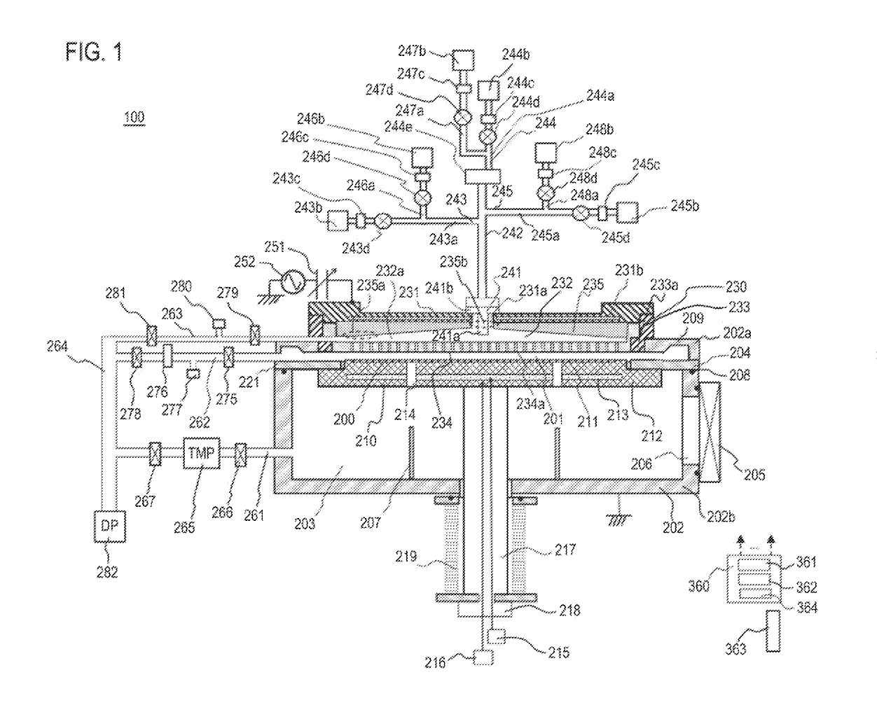

The configuration of a substrate processing apparatus 100 according to this embodiment is shown in FIG. 1. As shown in FIG. 1, the substrate processing apparatus 100 is configured as a single-wafer-type substrate processing apparatus.

### (Process Vessel)

As shown in FIG. 1, the substrate processing apparatus 100 includes a process vessel 202. The process vessel 202 is configured as, e.g., a flat airtight vessel with a circular cross-section. Further, the process vessel 202 is formed of metal material such as, e.g., aluminum (Al), stainless steel (SUS), etc. A process chamber 201, in which a wafer 200 (e.g., a silicon wafer, etc.) as a substrate is processed, and a transfer chamber 203 having a transfer space, through which the wafer 200 passes when the wafer 200 is transferred into the process chamber 201, are formed in the process vessel 202. The process vessel 202 includes an upper vessel 202a and a lower vessel 202b. A partition plate 204 is installed between the upper vessel 202a and the lower vessel 202b.

A substrate loading/unloading port 206 adjacent to a gate valve 205 is installed on a side surface of the lower vessel 202b, and the wafer 200 moves into and out of a transfer chamber (not shown) adjacent thereto through the substrate loading/unloading port 206. A plurality of lift pins 207 is installed in a bottom portion of the lower vessel 202b. Further, the lower vessel 202b is grounded.

A substrate support portion 210 configured to support the wafer 200 is installed within the process chamber 201. The substrate support portion 210 mainly includes a substrate mounting surface 211 on which the wafer 200 is mounted, a substrate mounting table 212 having the substrate mounting surface 211 on its surface, and a heater 213 as a heating source included in the substrate mounting table 212. Through holes 214, through which the lift pins 207 pass, are formed in positions corresponding to the lift pins 207, respectively, in the substrate mounting table 212.

The substrate mounting table 212 is supported by a shaft 217. The shaft 217 penetrates through a bottom portion of the process vessel 202 and is also connected to an elevation mechanism 218 outside of the process vessel 202. By operating the elevation mechanism 218 to lift or lower the shaft 217 and the substrate mounting table 212, the wafer 200 mounted on the substrate mounting surface 211 can be lifted or lowered. Further, a periphery of a lower end portion of the shaft 217 is covered with a bellows 219, and thus, the inside of the process vessel 202 is kept airtight.

The substrate mounting table 212 is lowered to a position (wafer transfer position) at which the substrate mounting surface 211 faces the substrate loading/unloading port 206 when the wafer 200 is transferred, while the substrate mounting table 212 is lifted until the wafer 200 reaches its processing position (wafer processing position) within the process chamber 201, as shown in FIG. 1, when the wafer 200 is processed.

Specifically, when the substrate mounting table 212 is lowered to the wafer transfer position, upper end portions of the lift pins 207 protrudes from an upper surface of the substrate mounting surface 211 and the lift pins 207 support the wafer 200 from below. Further, when the substrate mounting table 212 is lifted to the wafer processing position, the lift pins 207 are buried from the upper surface of the substrate mounting surface 211 and the substrate mounting surface 211 supports the wafer 200 from below. In addition, since the lift pins 207 are in direct contact with the wafer 200, it may be preferable that the lift pins 207 are formed of a material such as, e.g., quartz, alumina, etc.

A shower head 230 as a gas dispersion mechanism is installed in an upper portion (upstream side) of the process chamber 201. A buffer chamber 232 is installed in the shower head 230. The buffer chamber 232 has a buffer space 232a in its inner side. A through hole 231a, into which a first dispersion mechanism 241 is inserted, is formed in a lid 231 of the shower head 230. The first dispersion mechanism 241 includes a front end portion 241a that is inserted into the shower head and a flange 241b that is fixed onto the lid 231.

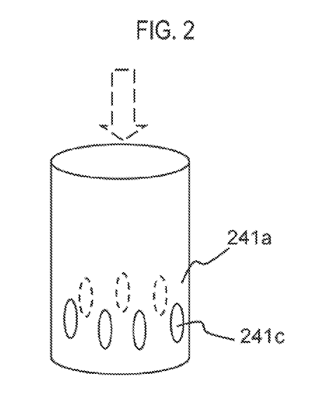

FIG. 2 is an explanatory view illustrating the front end portion 241a of the first dispersion mechanism 241. The dotted line arrow indicates a supply direction of a gas. The front end portion 241a is configured to have a columnar shape, e.g., a cylinder shape. Dispersion holes 241c are formed on the side surface of the cylinder. A gas supplied from a gas supply part (supply system) as described later is supplied to the buffer space 232a through the front end portion 241a and the dispersion holes 241c.

The lid 231 of the shower head is formed of a conductive metal and used as an electrode for generating plasma within the buffer space 232a or the process chamber 201. An insulating block 233 is installed between the lid 231 and the upper vessel 202a to insulate the lid 231 and the upper vessel 202a from each other.

The shower head 230 includes a dispersion plate 234 as a second dispersion mechanism configured to disperse a gas. The buffer chamber 232 is at the upstream side of this dispersion plate 234, and the process chamber 201 is at the downstream side of the dispersion plate 234. The process chamber 201 is adjacent to the shower head 230 through the dispersion plate 234. A plurality of through holes 234a is formed in the dispersion plate 234. The dispersion plate 234 is disposed to face the substrate mounting surface 211.

A shower head heating part 231b as a shower head temperature control part for controlling a temperature of the shower head 230 is installed in the lid 231. The shower head heating part 231b controls a temperature of the shower head 230 such that a gas supplied to the buffer space 232a is not reliquefied. For example, the shower head heating part 231b controls the shower head 230 to be heated to about 100 degrees C.

The dispersion plate 234 has, e.g., a disk shape. The through holes 234a are installed in the entire surface of the dispersion plate 234. Adjacent through holes 234a are disposed at, e.g., an equal distance, and the through hole 234a disposed in the outermost circumference is disposed on an outer side than a circumference of a wafer mounted on the substrate mounting table 212.

Further, a gas guide 235, which guides a gas supplied from the first dispersion mechanism 241 to the dispersion plate 234, is provided. The gas guide 235 has a shape in which its diameter increases in a direction toward the dispersion plate 234, and an inner side of the gas guide 235 has a pyramidal shape (e.g., a conic shape). The gas guide 235 is formed such that its lower end is positioned on a side outer than the through hole 234a formed in the outermost circumference of the dispersion plate 234.

The upper vessel 202a has a flange, and the insulating block 233 is mounted and fixed onto the flange. The insulating block 233 has a flange 233a, and the dispersion plate 234 is mounted and fixed onto the flange 233a. Further, the lid 231 is fixed to the upper surface of the insulating block 233. By having the structure described above, the lid 231, the dispersion plate 234, and the insulating block 233 can be removed in this order from above.

Further, in this embodiment, since a plasma generating part described later is connected to the lid 231, the insulating block 233, which is configured to prevent power from being transmitted to the upper vessel 202a, is installed. Also, the dispersion plate 234 and the lid 231 are installed on the insulating member. However, the present disclosure is not limited thereto. For example, in case that there is no plasma generating part, the dispersion plate 234 is fixed to the flange 233a and the lid 231 may be fixed to a portion other than the flange of the upper vessel 202a. That is, it may be any box structure in which the lid 231 and the dispersion plate 234 are removed in this order from above.

By the way, a film forming step described later includes a purge step of evacuating atmosphere of the buffer space 232a. During this film forming step, the purge step is performed to alternately supply different gases and also remove a residual gas from the process chamber 201 or the shower head 230 while the different gases are supplied. This alternate supply method is repeatedly performed several times until a desired film thickness is obtained, which takes time for film formation. Thus, when the alternate supply process is performed, it is required to shorten time as much as possible. Meanwhile, in order to enhance yield, it is required to uniformize a film thickness or film quality in the surface of a substrate.

Thus, in this embodiment, the dispersion plate that uniformly disperses a gas is provided and the volume of the buffer space 232a above the dispersion plate is configured to be small. For example, the volume of the buffer space 232a is configured to be smaller than that of the space within the process chamber 201. As such, the purge step of evacuating the atmosphere of the buffer space 232a can be shortened.

### (Supply System)

The first dispersion mechanism 241 is inserted and connected to the through hole 231a, which is formed in the lid 231 of the shower head 230. A common gas supply pipe 242 is connected to the first dispersion mechanism 241. A flange 241b is installed in the first dispersion mechanism 241, and fixed to the lid 231 and the flange of the common gas supply pipe 242 with a screw, etc.

The first dispersion mechanism 241 and the common gas supply pipe 242 communicate with each other inside the pipes, and thus, a gas supplied from the common gas supply pipe 242 is supplied into the shower head 230 through the first dispersion mechanism 241 and the through hole 231a.

A first gas supply pipe 243a, a second gas supply pipe 244a, and a third gas supply pipe 245a are connected to the common gas supply pipe 242. The second gas supply pipe 244a is connected to the common gas supply pipe 242 through a remote plasma part 244e.

A gas containing a first element is mainly supplied from a first gas supply system 243 including the first gas supply pipe 243a, and a gas containing a second element is mainly supplied from a second gas supply system 244 including the second gas supply pipe 244a. From a third gas supply system 245 including the third gas supply pipe 245a, an inert gas is mainly supplied when a wafer is processed, and a cleaning gas is mainly supplied when the shower head 230 or the process chamber 201 is cleaned.

### (First Gas Supply System)

A first gas supply source 243b, a mass flow controller (MFC) 243c, which is a flow rate controller (flow rate control part), and a valve 243d, which is an opening/closing valve, are installed in the first gas supply pipe 243a in this order from an upstream direction.

A gas containing a first element (hereinafter, referred to as a “first element-containing gas”) is supplied to the shower head 230 from the first gas supply pipe 243a through the MFC 243c, the valve 243d, and the common gas supply pipe 242.

The first element-containing gas is a precursor gas, i.e., one of process gases. In this case, the first element is, e.g., titanium (Ti). That is, the first element-containing gas is, e.g., a titanium-containing gas. Further, the first element-containing gas may be in any one of solid, liquid and gaseous states under the normal temperature and pressure. When the first element-containing gas is in a liquid state under the normal temperature and pressure, a vaporizer (not shown) may be installed between the first gas supply source 243b and the MFC 243c. Here, a case in which the first element-containing gas is in a gaseous state will be described.

A downstream end of the first inert gas supply pipe 246a is connected to the first gas supply pipe 243a at a downstream side of the valve 243d. An inert gas supply source 246b, an MFC 246c, which is a flow rate controller (flow rate control part), and a valve 246d, which is an opening/closing valve, are installed in the first inert gas supply pipe 246a in this order from the upstream direction.

Here, the inert gas is, e.g., a nitrogen (N₂) gas. Also, a rare gas such as e.g., a helium (He) gas, a neon (Ne) gas, an argon (Ar) gas, etc. in addition to the N₂ gas, may be used as the inert gas.

The first element-containing gas supply system 243 (also referred to as the titanium-containing gas supply system) includes the first gas supply pipe 243a, the MFC 243c, and the valve 243d.

Further, a first inert gas supply system includes the first inert gas supply pipe 246a, the MFC 246c, and the valve 246d. Also, it may be considered that the inert gas supply source 243b and the first gas supply pipe 243a are included in the first inert gas supply system.

In addition, it may be considered that the first gas supply source 243b and the first inert gas supply system are included in the first element-containing gas supply system 243.

### (Second Gas Supply System)

The remote plasma part 244e is installed at a downstream side of the second gas supply pipe 244a. At an upstream side of the second gas supply pipe 244a, a second gas supply source 244b, an MFC 244c, which is a flow rate controller (flow rate control part), and a valve 244d, which is an opening/closing valve, are installed in this order from the upstream direction.

A gas containing a second element (hereinafter, referred to as a “second element-containing gas”) is supplied into the shower head 230 from the second gas supply pipe 244a though the MFC 244c, the valve 244d, the remote plasma part 244e, and the common gas supply pipe 242. The second element-containing gas turns into a plasma state by the remote plasma part 244e and is irradiated onto the wafer 200.

The second element-containing gas is one of the process gases. Also, the second element-containing gas may be considered as a reaction gas or a modifying gas.

Here, the second element-containing gas contains a second element different from the first element. The second element is any one of, e.g., oxygen (O), nitrogen (N), and carbon (C). In this embodiment, the second element-containing gas is, e.g., a nitrogen-containing gas. Specifically, an ammonia (NH₃) gas is used as the nitrogen-containing gas.

The second element-containing gas supply system 244 (also referred to as the nitrogen-containing gas supply system) includes the second gas supply pipe 244a, the MFC 244c, and the valve 244d.

Further, a downstream end of the second inert gas supply pipe 247a is connected to the second gas supply pipe 244a at a downstream side of the valve 244d. An inert gas supply source 247b, an MFC 247c, which is a flow rate controller (flow rate control part), and a valve 247d, which is an opening/closing valve, are installed in the second inert gas supply pipe 247a in this order from the upstream direction.

An inert gas is supplied into the shower head 230 from the second inert gas supply pipe 247a through the MFC 247c, the valve 247d, the second gas supply pipe 244a, and the remote plasma part 244e. The inert gas acts as a carrier gas or a dilution gas in a thin film forming step S104 described later.

A second inert gas supply system includes the second inert gas supply pipe 247a, the MFC 247c, and the valve 247d. Also, it may be considered that the inert gas supply source 247b, the second gas supply pipe 244a, and the remote plasma part 244e are included in the second inert gas supply system.

Further, it may be considered that the second gas supply source 244b, the remote plasma part 244e, and the second inert gas supply system are included in the second element-containing gas supply system 244.

### (Third Gas Supply System)

A third gas supply source 245b, an MFC 245c, which is a flow rate controller (flow rate control part), and a valve 245d, which is an opening/closing valve, are installed in the third gas supply pipe 245a in this order from the upstream direction.

An inert gas as a purge gas is supplied into the shower head 230 from the third gas supply pipe 245a though the MFC 245c, the valve 245d, and the common gas supply pipe 242.

Here, the inert gas is, e.g., a nitrogen (N₂) gas. Also, a rare gas such as, e.g., a helium (He) gas, a neon (Ne) gas, or an argon (Ar) gas, in addition to the N₂ gas, may be used as the inert gas.

A downstream end of a cleaning gas supply pipe 248a is connected to the third gas supply pipe 245a at a downstream side of the valve 245d. A cleaning gas supply source 248b, an MFC 248c, which is a flow rate controller (flow rate control part), and a valve 248d, which is an opening/closing valve, are installed in the cleaning gas supply pipe 248a in this order from the upstream direction.

The third gas supply system 245 includes the third gas supply pipe 245a, the MFC 245c, and the valve 245d.

Further, a cleaning gas supply system includes the cleaning gas supply pipe 248a, the MFC 248c, and the valve 248d. Also, it may be considered that the cleaning gas supply source 248b and the third gas supply pipe 245a are included in the cleaning gas supply system.

In addition, it may be considered that the third gas supply source 245b and the cleaning gas supply system are included in the third gas supply system 245.

In a substrate treatment process, an inert gas is supplied into the shower head 230 from the third gas supply pipe 245a through the MFC 245c, the valve 245d, and the common gas supply pipe 242. Also, in the cleaning step, a cleaning gas is supplied into the shower head 230 from the third gas supply pipe 245a through the MFC 248c, the valve 248d, and the common gas supply pipe 242.

In the substrate treatment process, the inert gas supplied from the inert gas supply source 245b serves as a purge gas that purges gases collected in the process vessel 202 or the shower head 230. Also, in the cleaning step, the inert gas serves as a carrier gas or a dilution gas of the cleaning gas.

In the cleaning step, a cleaning gas supplied from the cleaning gas supply source 248b serves as a cleaning gas that removes a byproduct, etc. attached to the shower head 230 or the process vessel 202.

Here, the cleaning gas is, e.g., a nitrogen trifluoride (NF₃) gas. Also, as the cleaning gas, a hydrogen fluoride (HF) gas, a chlorine trifluoride (ClF₃) gas, a fluorine (F₂) gas, or the like may be used, and any combination thereof may also be used.

### (Plasma Generating Part)

A matcher 251 and a high frequency power source 252 are connected to the lid 231 of the shower head. By adjusting impedance with the high frequency power source 252 and the matcher 251, plasma is generated in the shower head 230 and the process chamber 201.

### (Exhaust System)

However, as the processing of the substrate is repeatedly performed, a residual gas or a byproduct generated when residual gases react with each other may adhere to an inner wall of the shower head such that the residual gases and/or the byproduct is gathered in the through holes 234a to cause clogging.

According to the result of research by the present inventors, clogging may cause the following problems.

First, a supply amount of gas becomes insufficient within a predetermined time. Clogging makes it difficult for a gas to pass, resulting in shortage of a supply amount of gas to the wafer 200. Since a film cannot reach a desired thickness when the supply amount of gas is insufficient, quality of the film or a semiconductor device may be degraded.

Second, a supply amount of gas to the surface of the substrate becomes non-uniform. Since clogging is not intentionally generated, for example, the through holes 234a disposed in a central portion of the dispersion plate 234 may not be clogged, while the through holes 234a disposed on the outer circumference of the dispersion plate 234 may be clogged.

In particular, in this embodiment, a distance between the edge portion 235a of the gas guide 235 and the dispersion plate 234 is shorter than a distance between the central portion 235b of the gas guide 235 and the dispersion plate 234, and thus, it would be appreciated that a vicinity of the edge portion 235a may have a high pressure. Thus, since a gas with a high pressure flows to the outer circumference of the dispersion plate 234 rather than the center of the dispersion plate 234, the through holes 234a disposed on the outer circumference may be easily clogged.

In this case, since the amounts of gas supplied to the outer circumference and the inner circumference of the wafer 200 become different from each other, a film thickness and film quality in the surface of the substrate are not even, which leads to degradation of yield.

Third, in the film forming step described later, the adherend within the through holes 234a may be stripped off. Specifically, in the film forming step described later, when the type of a supply gas is changed, the atmosphere of the process chamber 201 or the shower head 230 is evacuated, a gas comes into contact with the adherend, or a pressure is changed in order to supply a next gas such that the adherend within the through holes 234a are stripped to be separated. The separated adherend is attached onto the wafer 200, thereby degrading yield.

Since the foregoing problems arise simultaneously or solely, it is required to suppress clogging of the through holes 234a.

Thus, in this embodiment, a pressure detecting part 280 for detecting clogging of the through holes 234a is installed in the exhaust pipe 263 connected to the shower head 230. The pressure detecting part 280 will be described in detail later.

An exhaust system configured to evacuate the atmosphere of the process vessel 202 includes a plurality of exhaust pipes connected to the process vessel 202. Specifically, the exhaust system includes an exhaust pipe (a first exhaust pipe) 262 connected to the process chamber 201, an exhaust pipe (a second exhaust pipe) 263 connected to the shower head 230, and an exhaust pipe (a third exhaust pipe) 261 connected to the transfer chamber 203. Further, an exhaust pipe (a fourth exhaust pipe) 264 is connected to the downstream side of each of the exhaust pipes 261, 262, and 263.

The exhaust pipe 261 is connected to the side surface or the bottom surface of the transfer chamber 203. In the exhaust pipe 261, a turbo molecular pump (TMP) (a first vacuum pump) 265 is installed as a vacuum pump that realizes high vacuum or ultra-high vacuum. In the exhaust pipe 261, a valve 266 is installed as a first exhaust valve for the transfer space at the upstream side of the TMP 265. Also, in the exhaust pipe 261, a valve 267 is installed at the downstream side of the TMP 265. The valve 267 is closed during a shower head exhaust step or a process gas supply step described later to prevent an exhausted gas from being introduced into the TMP 265.

The exhaust pipe 262 is connected to the side of the process chamber 201 through an exhaust hole 221. An auto pressure controller (APC) 276, which is a pressure controller configured to control the inside of the process chamber 201 to a predetermined pressure, is installed in the exhaust pipe 262. The APC 276 includes a valve body (not shown) with an adjustable degree of opening, and adjusts a conductance of the exhaust pipe 262 according to instructions from a controller described later. In the exhaust pipe 262, a valve 278 is installed at the downstream side of the APC 276. Also, in the exhaust pipe 262, a valve 275 is installed at the upstream side of the APC 276. A pressure detecting part 277 for detecting a pressure of the exhaust pipe 262 is installed between the APC 276 and the valve 275. The exhaust pipe 262, the valve 275 and the APC 276 may be integrally referred to as a process chamber exhaust part. The valve 278 is closed during the shower head exhaust step described later to prevent an exhausted gas from being introduced into the pressure detecting part 277, the APC 276, and the process chamber 201.

The exhaust pipe 263 is connected to a wall surface (a second wall surface), which is different from a wall surface (first wall surface) connected to the process chamber 201, in the wall surfaces forming the shower head 230. More preferably, the exhaust pipe 263 is connected to a wall surface connected to a wall surface adjacent to the process chamber 201. In a height direction, the exhaust pipe 263 is connected between the dispersion holes 234a and a lower end of the gas guide 235. The exhaust pipe 263 has a valve 279. The pressure detecting part 280 for detecting a pressure of the exhaust pipe 263 is installed downstream of the valve 279. A valve 281 is installed in a lower stream of the pressure detecting part 280. The exhaust pipe 263, the valve 279, and the valve 281 may be integrally referred to as a shower head exhaust part. The valve 281 is closed during a process gas supply step described later to prevent a gas, which is exhausted from the process chamber 201, from being introduced to the pressure detecting part 280 or the inside of the buffer space 232a.

A dry pump (DP) 282 is installed in the exhaust pipe 264. As shown, the exhaust pipe 263, the exhaust pipe 262, and the exhaust pipe 261 are connected to the exhaust pipe 264 from the upstream side thereof, and the DP 282 is installed at the downstream of the exhaust pipes. The DP 282 evacuates the atmosphere of each of the buffer chamber 232, the process chamber 201, and the transfer chamber 203 through each of the exhaust pipe 263, the exhaust pipe 262, and the exhaust pipe 261. Further, when the TMP 265 operates, it also serves as an auxiliary pump thereof. That is, since it is difficult for the TMP 265, which is a high vacuum (or ultra-high vacuum) pump, to perform the exhaust to an atmospheric pressure by itself, the DP 282 is used as an auxiliary pump that performs the exhaust to the atmospheric pressure. For each valve of the exhaust system described above, for example, an air valve is used.

### (Pressure Detecting Part)

The pressure detecting part 277 is installed in the exhaust pipe 262, and the pressure detecting part 280 is installed in the exhaust pipe 263.

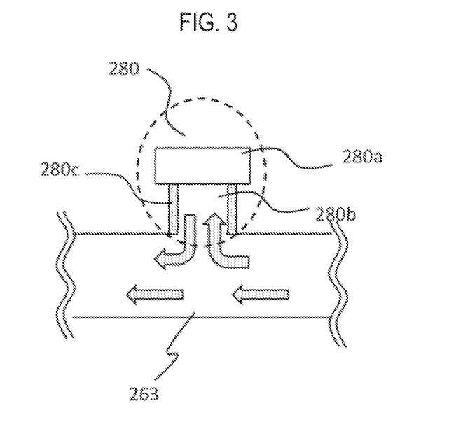

In this embodiment, as illustrated in FIG. 3, the pressure detecting part 280 is installed on a side surface of the exhaust pipe 263. The pressure detecting part 280 includes a sensor 280a for physically detecting a pressure of gas, a guide pipe 280b for guiding a gas flowing in the exhaust pipe 263 to the sensor 280a, and a temperature control part 280c for maintaining the guide pipe 280b at a predetermined temperature. The sensor 280a detects a pressure of gas guided as indicated by the arrows.

In this case, however, the gas which has moved from the exhaust pipe 263 to the guide pipe 280b may be attached to the wall of the guide pipe 280b. The reason is that the guide pipe 280b has a low temperature due to the problem of heat resistance of the sensor. The temperature of the guide pipe 280b is controlled to, e.g., about 50 degrees C., which is lower than that of the buffer space 232a. The buffer space 232a is heated to a temperature at which a gas is not reliquefied as described above, and a gas may be solidified or liquefied in the guide pipe 280b having a temperature lower than that of the buffer space 232a depending on a conductance or pressure condition.

Here, in a comparative example of this embodiment, a case where the pressure detecting part is installed at the upstream of the process chamber 201 may be taken into consideration. The upstream of the process chamber 201 refers to an upstream with respect to a direction, in which a process gas flows in the process gas supply step, as described later. Thus, it refers to a case where the pressure detecting part is installed in the buffer chamber 232 or the common gas supply pipe 242.

In the case where the pressure detecting part is installed in the common gas supply pipe 242, when a gas (process gas) is supplied to the process chamber through the common gas supply pipe 242 and the shower head, the gas may penetrate to the guide pipe and adhere to the wall of the guide pipe. In the adhered state, when an another gas (purge gas) is supplied into the shower head through the common gas supply pipe 242, the adherend is stripped off to be separated by a flow of the gas. The separated adherent is supplied to the shower head 230. Then, the adherent may enter the through holes 234a to cause firm clogging or adhere onto the wafer, such that yield may be further lowered. Moreover, for example, in an area (e.g., a corner portion of the guide pipe, etc.), which is rarely affected by the flow of gas, adherent may remain in the guide pipe. When the adherent remaining in the corner portion is liquefied, it may corrode the guide pipe itself.

When the pressure detecting part is installed on the wall forming the buffer chamber 232, the sensor of the pressure detecting part may be affected by heat of the shower head heating part 231b such that there is a possibility that the sensor itself is damaged. Further, in common with the case where the pressure detecting part is installed in the common gas supply pipe 242, there is a possibility of generating particles.

Additionally, here, a case in which clogging is detected by the pressure detecting part 277 may be considered. As described above, the volume within the process chamber 201 is greater than the volume of the buffer space 232a. Due to such a structure, a gas is dispersed in the vicinity of the pressure detecting part 277, rather than the exhaust pipe 263. Thus, it is difficult to detect an accurate pressure value, compared with the exhaust pipe 263.

Also, in this embodiment, an exhaust buffer chamber 209 is installed in the outer circumference of the process chamber 201. Thus, the sum of the volume of the space within the process chamber and the volume of the space within the buffer chamber 209 becomes greater than the volume of the buffer space 232a within the shower head 230. Accordingly, the dispersion of the gas within the process chamber 201 is more conspicuous, making it more difficult to detect an accurate pressure than the above configuration.

As described above, in this embodiment, the pressure detecting part 280 is installed in the exhaust pipe 263 to detect variations in pressure.

### (Controller)

The substrate processing apparatus 100 includes a controller 360 that controls the operations of the respective parts of the substrate processing apparatus 100. The controller 360 includes at least a computing part 361, a memory part 362, and a display screen 364. The controller 360 is connected to the respective components described above, and is configured to invoke a program or a recipe from the memory part 362 according to instructions from a higher controller or a user, and control the operations of the respective configurations depending on the contents thereof. Further, the controller 360 may be configured as a dedicated computer or may be configured as a general-purpose computer. For example, the controller 360 according to this embodiment may be configured by preparing an external recording medium 363 such as an external memory device (e.g., a magnetic tape, a magnetic disc such as a flexible disc, a hard disc, etc., an optical disc such as a CD, DVD, etc., a magneto-optical disc such as an MO, etc., or a semiconductor memory such as a USB memory (USB Flash Drive), a memory card, etc.), in which the program as described above is stored, and installing the program on the general-purpose computer using the external recording medium 363. Further, a means for supplying a program to a computer is not limited to a case in which the program is supplied through the external recording medium 363. For example, the program may be supplied by using a communication part such as the Internet, a dedicated line, etc., without being through the external recording medium 363. Also, the memory part 362 or the external recording medium 363 is configured as a non-transitory computer-readable recording medium. Hereinafter, these will be collectively referred to simply as a “recording medium.” In addition, when the term “recording medium” is used herein, it may include a case in which only the memory part 362 is included, a case in which only the external recording medium 363 is included, or a case in which both the memory part 362 and the external recording medium 363 are included. The display screen 364 displays substrate processing conditions or displays alarm information as described later.

### <Substrate Treatment Process>

Next, a step of forming a thin film on the wafer 200 using the substrate processing apparatus 100 will be described. Also, in the following description, the operations of the respective parts that constitute the substrate processing apparatus 100 are controlled by the controller 360.

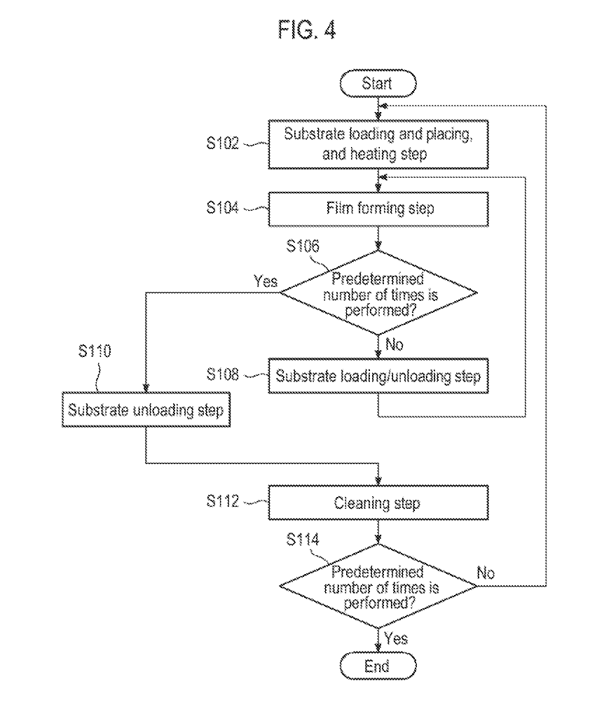

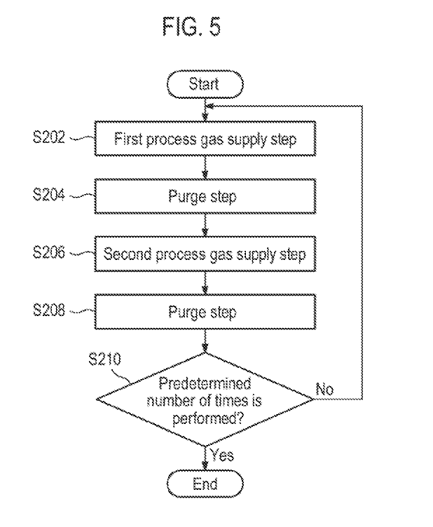

FIG. 4 is a flowchart illustrating a substrate treatment process according to this embodiment. FIG. 5 is a flowchart illustrating the details of a film forming step S104 of FIG. 4.

Hereinafter, an example of forming a titanium nitride film as a thin film on the wafer 200 using a TiCl₄ gas as a first process gas and an ammonia (NH₃) gas as a second process gas will be described.

### (Substrate Loading and Mounting Step S102)

In the substrate processing apparatus 100, the substrate mounting table 212 is lowered to a transfer position of the wafer 200, thereby allowing the lift pins 207 to penetrate through the through holes 214 of the substrate mounting table 212. As a result, the lift pins 207 are in a state in which they protrude from the surface of the substrate mounting table 212 by a predetermined height. Subsequently, the gate valve 205 is opened for allowing the transfer chamber 203 to communicate with a transfer chamber (not shown). And then, the wafer 200 is loaded into the transfer chamber 203 by using a wafer transfer device (not shown) from the transfer chamber, and the wafer 200 is transferred onto the lift pins 207 so as to be mounted. Thus, the wafer 200 is supported in a horizontal position above the lift pins 207 that protrude from the surface of the substrate mounting table 212.

When the wafer 200 is loaded into the process vessel 202, the wafer transfer device is retreated to the outside of the process vessel 202, and the gate valve 205 is closed to make the inside of the process vessel 202 airtight. Thereafter, the wafer 200 is mounted on the substrate mounting surface 211 provided on the substrate mounting table 212 by lifting the substrate mounting table 212, and further, the wafer 200 is lifted to the processing position within the process chamber 201 described above by lifting the substrate mounting table 212.

When the wafer 200 is lifted to the processing position within the process chamber 201 after it is loaded into the transfer chamber 203, the valve 266 and the valve 267 are closed. Thus, the communication between the transfer chamber 203 and the TMP 265 and the communication between the TMP 265 and the exhaust pipe 264 are blocked such that the evacuation of the transfer chamber 203 by the TMP 265 is terminated. Meanwhile, the valve 278 and the valve 275 are opened for allowing the process chamber 201 and the APC 276 to communicate with each other and also the APC 276 and the DP 282 to communicate with each other. The APC 276 adjusts a conductance of the exhaust pipe 263 to control the exhaust flow rate of the process chamber 201 by the DP 282, thereby maintaining the process chamber 201 to a predetermined pressure (e.g., a high vacuum of 10⁻⁵ to 10⁻¹ Pa).

Further, during this step, a N₂ gas may be supplied as an inert gas from the inert gas supply system into the process vessel 202 while the inside of the process vessel 202 is evacuated. That is, the N₂ gas may be supplied into the process vessel 202 by allowing at least the valve 245d of the third gas supply system to be opened while the inside of the process vessel 202 is evacuated with the TMP 265 or the DP 282.

In addition, when the wafer 200 is mounted on the substrate mounting table 212, a power is supplied to the heater 213 that is buried inside the substrate mounting table 212 such that the surface of the wafer 200 is controlled to have a predetermined temperature. The temperature of the wafer 200 has a range of, e.g., room temperature to 500 degrees C., and preferably, a range of room temperature to 400 degrees C. In this case, the temperature of the heater 213 is adjusted by controlling a state of conduction to the heater 213 based on temperature information detected by a temperature sensor (not shown).

### (Film Forming Step S104)

Subsequently, the thin film forming step S104 is performed. Hereinafter, the film forming step S104 will be described in detail with reference to FIG. 5. Further, the film forming step S104 is an alternate supply process which repeatedly performs the step of alternately supplying different process gases.

### (First Process Gas Supply Step S202)

When the wafer 200 is heated to reach a desired temperature, the valve 243d is opened and simultaneously the MFC 243c is adjusted such that a flow rate of the TiCl₄ gas becomes a predetermined flow rate. Further, the supply flow rate of the TiCl₄ gas has a range of, e.g., 100 sccm to 5000 sccm. In this case, the valve 245d of the third gas supply system is opened for supplying a N₂ gas from the third gas supply pipe 245a. In addition, the N₂ gas may be flowed from the first inert gas supply system. Also, prior to this step, the supply of the N₂ gas from the third gas supply pipe 245a may be initiated. The valve 279 is closed while the TiCl₄ gas is supplied to the process chamber through the buffer chamber 232. By allowing the valve 279 to be closed, the TiCl₄ gas is suppressed from be introduced to the guide pipe 280b of the pressure detecting part 280. By suppressing the introduction to the guide pipe 280b, attachment of a gas or a byproduct to the guide pipe 280b or backward flow thereof to the buffer chamber 232 is suppressed.

The TiCl₄ gas, which is supplied to the process chamber 201 through the first dispersion mechanism 241, is supplied onto the wafer 200. The TiCl₄ gas is made in contact with the top of the wafer 200, and thus, a titanium-containing layer is formed as a “first element-containing layer” on the surface of the wafer 200.

The titanium-containing layer is formed to have a predetermined thickness and a predetermined distribution depending on, e.g., an internal pressure of the process vessel 202, a flow rate of the TiCl₄ gas, a temperature of the substrate mounting table 212, a time required for passing the process chamber 201, or the like. Further, a predetermined film may be formed in advance on the wafer 200. Also, a predetermined pattern may be formed in advance in the wafer 200 or a predetermined film.

After a predetermined time has passed from the initiation of the supply of the TiCl₄ gas, the valve 243d is closed and the supply of the TiCl₄ gas is stopped. In step S202 described above, as shown in FIG. 4, the valve 275 and the valve 278 are opened, and the pressure of the process chamber 201 is controlled by the APC 276 to become a predetermined pressure. In step S202, the valves of the exhaust system other than the valve 275 and the valve 278 are all closed.

### (Purge Step S204)

Subsequently, a N₂ gas is supplied from the third gas supply pipe 245a to perform the purge of the shower head 230 and the process chamber 201. In this case, the valve 275 and the valve 278 are opened, and the pressure of the process chamber 201 is controlled by the APC 276 to become a predetermined pressure. Meanwhile, the valves of the exhaust system other than the valve 275 and the valve 278 are all closed. Thus, the TiCl₄ gas that is not coupled with the wafer 200 in the first process gas supply step S202 is removed from the process chamber 201 through the exhaust pipe 263 by the DP 282. The pressure detecting part 277 detects a pressure of gas that has passed through the exhaust pipe 263 and detects a pressure of the process chamber 201.

Subsequently, a N₂ gas is supplied from the third gas supply pipe 245a to perform the purge of the shower head 230. In this case, the pressure detecting part 280 is in an actuated state. The valve 275 and the valve 278 are closed, while the valve 279 and the valve 281 are opened. The other valves of the exhaust system remain in a closed state. That is, when the purge of the shower head 230 is performed, the communication between the process chamber 201 and the APC 276 is blocked, the communication between the APC 276 and the exhaust pipe 264 is blocked, and the pressure control by the APC 276 is stopped. Meanwhile, the buffer space 232a and the DP 282 are allowed to communicate with each other. Thus, the TiCl₄ gas remaining within the shower head 230 (the buffer space 232a) is exhausted by the DP 282 through the exhaust pipe 263 from the shower head 230. In this step, the pressure detecting part 280 detects a pressure of the exhaust pipe 263. Further, in this case, the valve 278 at the downstream side of the APC 276 may be opened.

When the purge of the shower head 230 is terminated, the valve 278 and the valve 275 are opened for resuming a pressure control by the APC 276 while the valve 279 is closed for blocking the communication between the shower head 230 and the exhaust pipe 264. The other valves of the exhaust system remain in a closed state. In this case, the supply of the N₂ gas from the third gas supply pipe 245a also continues, and the purge of the shower head 230 and the process chamber 201 continues. Also, the purge through the exhaust pipe 262 and the purge through the exhaust pipe 263 may be performed at the same time.

Here, the pressure values detected by the pressure detecting part 277 and the pressure detecting part 280 are delivered to the controller 260 and a pressure value determining step described later is performed. In this step, when it is determined that clogging is made to a degree sufficient for negatively affecting the process, for example, the film forming step S104 is stopped. Alternatively, a film formation of a current lot is performed, and thereafter, the apparatus is stopped. The pressure value determining step will be described in detail later.

### (Second Process Gas Supply Step S206)

After the purge step S204, the valve 244d is opened for initiating a supply of an ammonia gas in a plasma state into the process chamber 201 through the remote plasma part 244e and the shower head 230.

In this case, the MFC 244c is adjusted such that the flow rate of the ammonia gas becomes a predetermined flow rate. Further, the supply flow rate of the ammonia gas has a range of, e.g., 100 sccm to 5000 sccm. In addition, along with the ammonia gas, a N₂ gas may be flowed as a carrier gas from the second inert gas supply system. Also, in this step, the valve 245d of the third gas supply system is opened for supplying the N₂ gas from the third gas supply pipe 245a.

The ammonia gas in a plasma state supplied to the process vessel 202 through the first dispersion mechanism 241 is supplied onto the wafer 200. The titanium-containing layer that is already formed is modified by the plasma of the ammonia gas, thereby forming a layer containing, e.g., a titanium element and a nitrogen element, on the wafer 200.

The modified layer is formed to have a predetermined thickness, a predetermined distribution, and a predetermined penetration depth of a nitrogen component, etc. with respect to the titanium-containing layer depending on, e.g., an internal pressure of the process vessel 202, a flow rate of the nitrogen-containing gas, a temperature of the substrate mounting table 212, a power supply state of the plasma generating part, etc.

After a predetermined period of time has passed, the valve 244d is closed and the supply of the nitrogen-containing gas is stopped.

Also, in step S206, the valve 275 and the valve 278 are opened, and the pressure of the process chamber 201 is controlled to become a predetermined pressure by the APC 276, in common with S202 described above. Further, the valves of the exhaust system other than the valve 275 and the valve 278 are all closed.

### (Purge Step S208)

Subsequently, a purge step that is similar to S204 is performed. Since the respective parts operate in the same manner as those of S204 described above, descriptions thereof will be omitted.

### (Determination Step S210)

The controller 360 determines whether the 1 cycle described above is performed a predetermined number of times (n cycle).

When a predetermined number of times is not performed (“NO” in step S210), the cycle of the first process gas supply step S202, the purge step S204, the second process gas supply step S206, and the purge step S208 is repeated. When the predetermined number of times is performed (“YES” in step S210), the processing illustrated in FIG. 5 is terminated.

Returning to the descriptions of FIG. 4, subsequently, a substrate unloading step S106 is performed.

### (Substrate Unloading Step S106)

In the substrate unloading step S106, the substrate mounting table 212 is lowered for allowing the wafer 200 to be supported on the lift pins 207 that protrude from the surface of the substrate mounting table 212. Thus, the wafer 200 is placed in a transfer position from a processing position. Thereafter, the gate valve 205 is opened for allowing the wafer 200 to be unloaded to the outside of the process vessel 202 using the wafer transfer device. In this case, the valve 245d is closed for stopping the supply of the inert gas into the process vessel 202 from the third gas supply system.

Subsequently, when the wafer 200 is moved to the transfer position, the valves 266 and 267 are closed for blocking the communication between the transfer chamber 203 and the exhaust pipe 264. Meanwhile, the valve 266 and the valve 267 are opened for evacuating the atmosphere of the transfer chamber 203 by the TMP 265 (and the DP 282). Thus, the process vessel 202 in a high vacuum (ultra-high vacuum) state (e.g., 10⁻⁵ Pa or less) is maintained and the pressure difference from the transfer chamber, which is similarly maintained in a high vacuum (ultra-high vacuum) state (e.g., 10⁻⁶ Pa or less), is reduced. In this state, the gate valve 205 is opened, and the wafer 200 is unloaded from the process vessel 202 to the transfer chamber.

### (Processing Number Determination Step S108)

After the wafer 200 is unloaded, it is determined whether the thin film forming step has reached a predetermined number of times. When it is determined that the predetermined number of times is reached, the processing is terminated. When it is determined that the predetermined number of times is not reached, the flow returns to the substrate loading and mounting step S102 in order to initiate a processing of a next wafer 200 which is waiting.

### (Shower Head Pressure Value Determining Step)

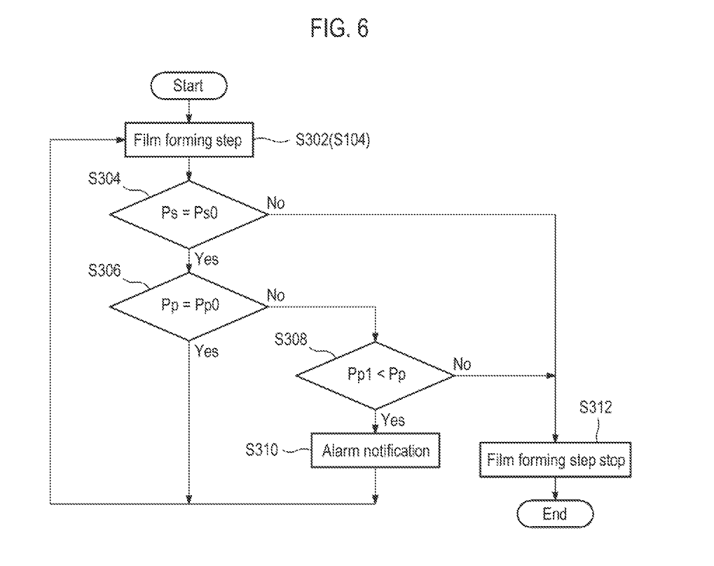

Subsequently, the pressure value determining step will be described with reference to FIG. 6.

In the purge step S204 (or S208) of the film forming step S104 (S302 of FIG. 6), a pressure value P_{P} detected by the pressure detecting part 277 or a pressure value P_{S} detected by the pressure detecting part 280 are input to the controller 360.

### (Shower Head Pressure Value Determining Step S304)

The controller 360 compares the pressure value P_{S} with a shower head pressure reference value P_{S0} that is previously stored in the storage part 362. The shower head pressure reference value P_{S0} refers to a pressure range determined as a degree to which clogging does not negatively affect the substrate processing.

A relationship between clogging made in the dispersion plate 234 and a pressure detected by the pressure detecting part 280 will be described. In general, a pressure, a flow rate of gas, and a conductance have the following relationship:

P (pressure)×C (conductance)=Q (flow rate of gas)

In the pressure detecting part 280 of this embodiment, the foregoing relationship is expressed as follows:

P_{S}×C_{S}=Q_{S}

where P_{S}: a value detected by the pressure detecting part 280,

C_{S}: a conductance of the exhaust pipe 263, and

Q_{S}: a flow rate of gas flowing in the exhaust pipe 263.

An amount of gas flowing from the buffer chamber 232 to the process chamber 201 through the dispersion plate 234 when the dispersion plate 234 is clogged, becomes smaller than that when a case in which there is no clogging. This is because the gas stays in the clogged portion and moves to the exhaust pipe 263 having a conductance higher than that of the clogged portion. P and Q are in a proportional relation. Thus, considering that the conductance of the exhaust pipe 263 is uniform, after the clogging, the pressure P_{S} also increases when Q_{S} increases.

Here, returning to the description of S304 of FIG. 6, when “P_{S}=P_{S0}”, that is, in case where the detected pressure is within a predetermined range, it is determined as “YES.” Thereafter, a Process Chamber Pressure Determining Step S306 is performed as a next step.

When it is not “P_{S}=P_{S0},” for example, in case of “P_{S}>P_{S0},” it is determined as “NO” and S312 is performed. In this case, since the pressure is higher than the predetermined pressure, it is determined that the dispersion plate 234 has been clogged due to the foregoing reasons. After the film forming step is stopped in step S314, maintenance is conducted by exchanging or cleaning the dispersion plate 234.

When it is not “P_{S}=P_{S0},” for example, in case of “P_{S}<P_{S0}”, it is determined as “NO” and S312 is performed. In this case, it is determined that detection was erroneously performed or there is an error in the sensor. After the film forming step is stopped in step S312, it is checked whether the pressure detecting part 280 or the DP 282 has an error.

### (Process Chamber Pressure Determining Step S306)

In the process chamber pressure determining step S306, the pressure value Pₚ detected by the pressure detecting part 277 is compared with the shower head pressure reference value Pₚ₀ that is previously stored in the storage part 362. Pₚ₀ refers to a pressure range of a normal film forming step.

In the pressure detecting part 277 of this embodiment, the foregoing relationship is expressed as follows:

Pₚ×Cₚ=Qₚ

where Pₚ: a value detected by the pressure detecting part 277,

Cₚ: a conductance of the exhaust pipe 262, and

Qₚ: a flow rate of gas flowing in the exhaust pipe 262.

An amount of gas flowing from the buffer chamber 232 to the process chamber 201 through the dispersion plate 234 when the dispersion plate 234 is clogged, becomes smaller than that when a case in which there is no clogging. This is because the gas stays in the clogged portion and moves to the exhaust pipe 262 having a conductance higher than that of the clogged portion. P and Q are in a proportional relation. Thus, considering that the conductance of the exhaust pipe 263 is uniform, after the clogging, the pressure P_{P} also decreases when Q_{P} decreases.

Here, returning to the description of S306 of FIG. 6, when “P_{P}=P_{P0}”, that is, in case where the detected pressure is within a predetermined range, it is determined as “YES.” Thereafter, the film forming step is continuously performed.

When “P_{P}=P_{P0}” is not satisfied, it is determined as “NO” and a next step S308 is performed.

### (Alarm Notification Determining Step S308)

In step S308, it is determined whether the detected pressure value Pₚ is greater than Pₚ₁ (i.e., whether “Pₚ₁<Pₚ”). When “Pₚ₁<Pₚ,” it is determined as “YES,” and an alarm notification step S310 is performed. Pₚ₁ is a reference value to conduct maintenance. In case where it is supposed that clogging has occurred but it has not reached a point to perform maintenance yet, it is determined as “YES” and a notification of the corresponding state is performed. In case of “NO,” step S312 is performed.

### (Alarm Notification Step S310)

When it is determined as “YES” in step S308, alarm information is displayed on a display screen 364 and a notification of alarm is provided to a user. Also, although alarm is illustrated as being displayed on the controller screen so as to be notified in this embodiment, but the present disclosure is not limited thereto and, for example, notification may be performed by a lamp, a sound, etc. After the alarm notification, the flow returns to the film forming step S302 (S104).

### (Film Forming Step Stop S312)

In case where it is determined as “NO” in the alarm notification determining step S308, that is, when Pₚ is lower than Pₚ₁, it may be determined that clogging has occurred to a degree sufficient for affecting film formation and the film forming step is stopped. Here, it is described that the film forming step is stopped, but the film forming step may be stopped after performing processing by 1 lot, rather than being immediately stopped. After stopping, maintenance such as exchanging or cleaning of the shower head is performed.

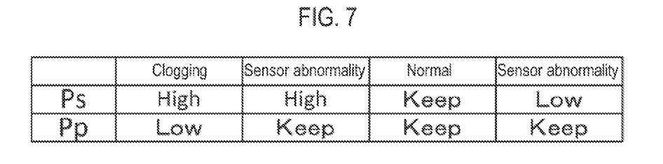

When pressure is detected as described above, an error of the sensor may also be simultaneously detected. Detection of an error of the sensor will be described with reference to the table of FIG. 7. The table shows comparison with the reference pressures P_{S0} and P_{P0}. “High” indicates a case where a pressure value higher than reference pressure values was detected, and “Keep” indicates that the detected pressure value is within a range of the reference pressure values, and “Low” indicates a case where the detected pressure value is lower than the reference pressure values.

According to the measurement results, in case where the pressure of the shower head side is high and the pressure of the process chamber side is low, it is determined that the dispersion plate 234 has been clogged as described above. This is because due to the clogging, the conductance of the first exhaust pipe decreases while the conductance of the second exhaust pipe increases.

According to the measurement results, in case where the pressure of the shower head side is high and the pressure of the process chamber side is within the reference pressure range, it is determined that the sensor of the pressure detecting part 277 or the pressure detecting part 280 is abnormal. As described above, when the dispersion plate 234 is clogged, P_{P} should be “Low.” However, since it is “Keep,” it is determined that the sensor is abnormal. In this case, for example, the film forming step is immediately stopped, or stopped after the processing of the current lot is terminated.

According to the measurement results, in case where both the pressure of the side of the shower head 230 and the pressure of the side of the process chamber 201 are within the reference pressure range, it is determined as normal.

According to the measurement results, in case where the pressure of the side of the shower head 230 is low and the pressure of the side of the process chamber 201 is within the reference pressure range, it is determined that the sensor of the pressure detecting part 277 or the pressure detecting part 280 is abnormal. As described above, when the dispersion plate 234 is clogged, P_{S} should be “High” and when the dispersion plate 234 is not clogged, P_{S} should be “Keep.” However, since P_{S} is “Low” according to the result of the pressure detection, it is determined that the sensor is abnormal. In this case, for example, the film forming step is immediately stopped, or stopped after the processing of the current lot is terminated.

While the film forming technique has been described above as various typical embodiments of the present disclosure, the present disclosure is not limited to these embodiments. For example, the present disclosure may also be applied to a case in which any other substrate processing is performed such as a film forming process, a diffusion process, a oxidizing process, a nitriding process, a lithography process, etc., in addition to the thin film process illustrated above. Further, the present disclosure may also be applied to any other substrate processing apparatus such as a thin film forming apparatus, an etching apparatus, an oxidizing processing apparatus, a nitriding processing apparatus, an application apparatus, a heating apparatus, etc., in addition to the annealing processing apparatus. In addition, some of the components of a certain embodiment may be substituted with components of other embodiments and components of other embodiments may also be added to components of a certain embodiment. Moreover, with respect to some of the components of each embodiment, other components may also be added, deleted, and/or substituted.

Further, even though each pressure is detected during the purge step, but the present disclosure is not limited thereto. For example, after the wafer is unloaded, a pressure may be detected and clogging is checked as one step of the maintenance step.

Also, in the foregoing embodiment, TiCl₄ is described as an example of the first element-contained gas and Ti is described as an example of the first element, but the present disclosure is not limited thereto. For example, the first element may be various other elements such as Si, Zr, Hf, etc. Also, NH₃ is described as an example of the second element-contained gas and N is described as an example of the second element, but the present disclosure is not limited thereto. For example, 0, etc. may be used as the second element.

### <Aspects of the Present Disclosure>

Hereinafter, some aspects of the present disclosure are described as supplementary notes.

### (Supplementary Note 1)

According to one aspect of the present disclosure, there is provided a substrate processing apparatus, including:

a process chamber configured to process a substrate;

a shower head installed at an upstream side of the process chamber;

a gas supply pipe connected to the shower head;

a first exhaust pipe connected to a downstream side of the process chamber;

a second exhaust pipe connected to a second wall surface, which is different from a first wall surface adjacent to the process chamber, in wall surfaces forming the shower head;

a pressure detecting part installed in the second exhaust pipe; and

a control part configured to control each of the process chamber, the shower head, the gas supply pipe, the first exhaust pipe, the second exhaust pipe, and the pressure detecting part.

### (Supplementary Note 2)

In the apparatus according to Supplementary Note 1, preferably, the shower head includes a plurality of dispersion holes formed in the first wall surface and an exhaust pipe connected to the second wall surface.

### (Supplementary Note 3)

In the apparatus according to Supplementary Note 2, preferably, in the shower head, a gas guide, which guides a gas, is formed above the first wall surface and the second exhaust pipe is connected between the first wall surface and a lower end of the gas guide in a height direction.

### (Supplementary Note 4)

In the apparatus according to any one of Supplementary Notes 1 to 3, preferably, a valve is installed upstream of the pressure detecting part of the second exhaust pipe.

### (Supplementary Note 5)

In the apparatus according to any one of Supplementary Notes 1 to 4, preferably, an exhaust buffer chamber configured to buffer exhaust from the process chamber is installed in an outer circumference of the process chamber, and a volume of a buffer space within the shower head is configured to be smaller than a sum of a volume of a space within the process chamber and a volume of a space within the exhaust buffer chamber.

### (Supplementary Note 6)

In the apparatus according to any one of Supplementary Notes 1 to 5, preferably, the volume of the buffer space within the shower head is configured to be smaller than that of the process chamber.

### (Supplementary Note 7)

In the apparatus according to any one of Supplementary Notes 1 to 6, preferably, a shower head temperature control part configured to control a temperature of the buffer space within the shower head is installed in the shower head, and the control part is configured to control the shower head temperature control part such that a temperature of the pressure detecting part is lower than that of the buffer space within the shower head.

### (Supplementary Note 8)

In the apparatus according to any one of Supplementary Notes 1 to 7, preferably, the control part is configured to alternately supply a precursor gas and a reaction gas that reacts with the precursor gas to the process chamber through the shower head, supply an inert gas between the supply of the precursor gas and the supply of the reaction gas, and control the valve installed in the second exhaust pipe such that the valve is in an open state while the inert gas is supplied.

### (Supplementary Note 9)

The apparatus according to any one of Supplementary Notes 1 to 8 preferably further includes an alarm notification part, wherein the control part is configured to allow the alarm notification part to perform notification of alarm when it is determined that a pressure value detected by the pressure detecting part is not within a predetermined range.

### (Supplementary Note 10)

According to another aspect of the present disclosure, there is provided a method of manufacturing a semiconductor device, in the apparatus according to any one of Supplementary Notes 1 to 8, preferably, the method including:

loading the substrate into the process chamber;

processing the substrate by evacuating atmosphere of the process chamber from the first exhaust pipe connected to the process chamber while supplying a process gas to the shower head installed upstream of the process chamber; and

evacuating the atmosphere of the shower head from the second exhaust pipe connected to the second wall surface that is different from the first wall surface adjacent to the process chamber, in the wall surfaces forming the shower head while supplying the inert gas to the shower head installed upstream of the process chamber, and detecting a pressure by the pressure detecting part installed in the second exhaust pipe.

### (Supplementary Note 11)

According to another aspect of the present disclosure, there is provided a program for executing the sequences including:

loading a substrate into a process chamber;

processing the substrate by evacuating atmosphere of the process chamber from a first exhaust pipe connected to the process chamber while supplying a process gas to a shower head installed upstream of the process chamber; and

evacuating the atmosphere of the shower head from a second exhaust pipe connected to a second wall surface that is different from a first wall surface adjacent to the process chamber, in wall surfaces forming the shower head while supplying an inert gas to the shower head installed upstream of the process chamber, and detecting a pressure by a pressure detecting part installed in the second exhaust pipe.

### (Supplementary Note 12)

According to another aspect of the present disclosure, there is provided a non-transitory computer-readable recording medium storing a program for executing the sequences including:

loading a substrate into a process chamber;

processing the substrate by evacuating atmosphere of the process chamber from a first exhaust pipe connected to the process chamber while supplying a process gas to a shower head installed upstream of the process chamber; and

evacuating the atmosphere of the shower head from a second exhaust pipe connected to a second wall surface that is different from a first wall surface adjacent to the process chamber, in wall surfaces forming the shower head while supplying an inert gas to the shower head installed upstream of the process chamber, and detecting a pressure by a pressure detecting part installed in the second exhaust pipe.

According to the present disclosure in some embodiments, it is possible to suppress generation of a byproduct, even in the complicated structure described above.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

1. A substrate processing apparatus, comprising:
a process chamber configured to process a substrate;
a shower head installed at an upstream side of the process chamber;
a gas supply pipe connected to the shower head;
a first exhaust pipe connected to a downstream side of the process chamber;
a second exhaust pipe connected to a second wall surface, which is different from a first wall surface adjacent to the process chamber, in wall surfaces forming the shower head;
a pressure detecting part installed in the second exhaust pipe;
a determining part configured to determine that the shower head is clogged when a pressure value detected by the pressure detecting part is higher than a predetermined value; and
a control part configured to control each of the process chamber, the shower head, the gas supply pipe, the first exhaust pipe, the second exhaust pipe, the pressure detecting part, and the determining part.

2. The apparatus of claim 1, wherein the shower head includes a plurality of dispersion holes formed in the first wall surface and the second exhaust pipe is connected to the second wall surface.

3. The apparatus of claim 2, wherein in the shower head, a gas guide, which guides a gas, is formed above the first wall surface and the second exhaust pipe is connected between the first wall surface and a lower end of the gas guide in a height direction.

4. The apparatus of claim 3, wherein a valve is installed upstream of the pressure detecting part of the second exhaust pipe.

5. The apparatus of claim 4, wherein an exhaust buffer chamber configured to buffer exhaust from the process chamber is installed in an outer circumference of the process chamber, and a volume of a buffer space within the shower head is configured to be smaller than a sum of a volume of a space within the process chamber and a volume of a space within the exhaust buffer chamber.

6. The apparatus of claim 5, wherein the volume of the buffer space within the shower head is configured to be smaller than that of the process chamber.

7. The apparatus of claim 6,
wherein a shower head temperature controller configured to control a temperature of the buffer space within the shower head is installed in the shower head, and
wherein the control part controls the shower head temperature controller such that a temperature of the pressure detecting part is lower than that of the buffer space within the shower head.

8. The apparatus of claim 7, wherein the control part is configured to alternately supply a precursor gas and a reaction gas that reacts with the precursor gas to the process chamber through the shower head, supply an inert gas between the supply of the precursor gas and the supply of the reaction gas, and control the valve installed in the second exhaust pipe such that the valve installed in the second exhaust pipe is in an open state while the inert gas is supplied.

9. The apparatus of claim 8, further comprising:
an alarm notification part,
wherein the control part is configured to allow the alarm notification part to perform notification of alarm when it is determined that a pressure value detected by the pressure detecting part is not within a predetermined range.

10. The apparatus of claim 1, wherein a valve is installed upstream of the pressure detecting part of the second exhaust pipe.

11. The apparatus of claim 10, wherein an exhaust buffer chamber configured to buffer exhaust from the process chamber is installed in an outer circumference of the process chamber, and a volume of a buffer space within the shower head is configured to be smaller than a sum of a volume of a space within the process chamber and a volume of a space within the exhaust buffer chamber.

12. The apparatus of claim 11, wherein the volume of the buffer space within the shower head is configured to be smaller than that of the process chamber.

13. The apparatus of claim 12,
wherein a shower head temperature controller configured to control a temperature of the buffer space within the shower head is installed in the shower head, and
wherein the control part controls the shower head temperature controller such that a temperature of the pressure detecting part is lower than that of the buffer space within the shower head.

14. The apparatus of claim 1, wherein an exhaust buffer chamber configured to buffer exhaust from the process chamber is installed in an outer circumference of the process chamber, and a volume of a buffer space within the shower head is configured to be smaller than a sum of a volume of a space within the process chamber and a volume of a space within the exhaust buffer chamber.

15. The apparatus of claim 14, wherein the volume of the buffer space within the shower head is configured to be smaller than that of the process chamber.

16. The apparatus of claim 15,
wherein a shower head temperature controller configured to control a temperature of the buffer space within the shower head is installed in the shower head, and
wherein the control part controls the shower head temperature controller such that a temperature of the pressure detecting part is lower than that of the buffer space within the shower head.

17. The apparatus of claim 1, wherein a volume of a buffer space within the shower head is configured to be smaller than that of the process chamber.

18. The apparatus of claim 17,
wherein a shower head temperature controller configured to control a temperature of the buffer space within the shower head is installed in the shower head, and
wherein the control part controls the shower head temperature controller such that a temperature of the pressure detecting part is lower than that of the buffer space within the shower head.

19. The apparatus of claim 1,
wherein a shower head temperature controller configured to control a temperature of the buffer space within the shower head is installed in the shower head, and
wherein the control part controls the shower head temperature controller such that a temperature of the pressure detecting part is lower than that of the buffer space within the shower head.
